(19) United States
(12) Patent Application Publication
(10) Pub. No.: US 2023/0085242 A1
(43) Pub. Date: Mar. 16, 2023

(54) THERMALLY CONDUCTIVE SILICONE COMPOSITION AND SILICONE THERMAL INTERFACE MATERIAL

(71) Applicant: Panasonic Intellectual Property Management Co., Ltd., Osaka (JP)

(72) Inventors: Keiichi KOMATSU, Osaka (JP); Hiroshi YAMAMOTO, Osaka (JP)

(21) Appl. No.: 17/801,747

(22) PCT Filed: Feb. 5, 2021
(86) PCT No.: PCT/JP2021/004396

§ 371 Date: Aug. 23, 2022

(30) Foreign Application Priority Data
Feb. 26, 2020 (JP) 2020-030913

(51) Int. Cl. C09K 5/14; C08G 77/04; C08K 7/00; H05K 7/20

(52) U.S. Cl. CPC C09K 5/14; C08G 77/04; C08K 7/00; H05K 7/2039; C08K 2201/001

(57) ABSTRACT

A thermally conductive silicone composition contains a silicone component (A) and a polyhedral alumina filler (B) having a gelatinization ratio equal to or higher than 80%.

### TECHNICAL FIELD

The present disclosure relates to a thermally conductive silicone composition and a silicone thermal interface material.

### BACKGROUND ART

The heat generated by an electronic or electrical component is transferred to a heat dissipator (heat sink) by interposing a thermal interface material between an electrical component such as a transistor or a central processing unit (CPU) of a computer and the heat dissipator. Patent Literature 1 discloses a thermally conductive silicone rubber composition in which a thermally conductive inorganic filler that has been subjected to surface treatment with a silane coupling agent is dispersed in silicone rubber.

### CITATION LIST

### Patent Literature

Patent Literature 1: JP H11-209618 A

### SUMMARY OF INVENTION

As electronic and electrical components have been integrated more and more densely, for example, the quantity of heat generated by the electronic and electrical components tend to increase more and more significantly. In addition, when a plurality of electronic and electrical components of mutually different sizes are mounted on a single board, the heat generated by those electronic and electrical components needs to be transferred efficiently through a thermal interface material.

The problem to be overcome by the present disclosure is to provide a thermally conductive silicone composition with the ability to improve the thermal conductivity of a silicone thermal interface material and also provide a silicone thermal interface material made of the thermally conductive silicone composition.

A thermally conductive silicone composition according to an aspect of the present disclosure contains: a silicone component (A); and a polyhedral alumina filler (B) having a gelatinization ratio equal to or higher than 80%.

A silicone thermal interface material according to another aspect of the present disclosure is made of the thermally conductive silicone composition described above and includes: a silicone resin matrix made of the silicone component (A); and the polyhedral alumina filler (B) dispersed in the silicone resin matrix.

### BRIEF DESCRIPTION OF DRAWINGS

FIG. 1 is a schematic cross-sectional view of an electronic device according to an exemplary embodiment of the present disclosure.

### DESCRIPTION OF EMBODIMENTS

A thermally conductive silicone composition according to an exemplary embodiment is used to make a silicone thermal interface material. The thermally conductive silicone composition contains: a silicone component (A); and a polyhedral alumina filler (B) having a gelatinization ratio equal to or higher than 80%.

The silicone component (A) may be, for example, reactive curing liquid silicone rubber or silicone gel. The silicone component (A) may be a two-part component or a one-part component, whichever is appropriate. The silicone component (A) contains a reactive organic silicon compound such as organo polysiloxane and a curing agent and may further contain a catalyst as needed. The curing agent contains, for example, at least one of organo hydrogen polysiloxane or an organic peroxide. The catalyst may be, for example, a platinum-based catalyst. Note that these are only exemplary components of the silicone component (A) and should not be construed as limiting.

The polyhedral alumina filler (B) having a gelatinization ratio equal to or higher than 80% may effectively reduce the heat resistance of the silicone thermal interface material. This is probably because in the silicone thermal interface material, respective particles of the polyhedral alumina filler (B) tend to make plane contact with each other, thus often increasing the efficiency of heat transfer between the particles. In addition, the polyhedral alumina filler (B) has a gelatinization ratio equal to or higher than 80%, and therefore, often has high thermal conductivity, which would often further increase the heat transfer efficiency via the particles of the polyhedral alumina filler (B). The gelatinization ratio is more preferably equal to or higher than 110% and is even more preferably equal to or higher than 120%.

Note that the gelatinization ratio of the polyhedral alumina filler (B) is calculated, based on the peak height (I_{25.6}) of an alumina α-phase appearing at a point where 2θ=25.6 degrees and the peak height (I₄₆) of γ-phase, η-phase, X-phase, κ-phase, θ-phase, and δ-phase appearing at a point where 2θ=46 degrees in a diffraction spectrum of the polyhedral alumina filler (B) obtained by a powder X-ray diffraction analyzer, by I_{25.6}/(I_{25.6}+I₄₆)×100 (%).

The polyhedral alumina filler (B) preferably has a thermal conductivity equal to or greater than 30 W/m·k. In that case, the heat resistance of the silicone thermal interface material may be reduced particularly effectively. Such high thermal conductivity of the polyhedral alumina filler (B) is achieved by the high gelatinization ratio of the polyhedral alumina filler (B).

Also, the shape of the polyhedral alumina filler (B) may be confirmed by observation through a scanning electron microscope (SEM). If the number of faces recognized through the electron microscope in the particles of the polyhedral alumina filler (B) is equal to or greater than 5 and equal to or less than 150, for example, then the alumina filler may be determined to be a polyhedron.

A distribution curve showing a relationship between the number of particles and the number of faces of particles of the polyhedral alumina filler (B) (i.e., a distribution curve, of which the ordinate indicates the number of particles and the abscissa indicates the number of faces of the particles) preferably has a maximum peak at a point where the number of faces of the particles is equal to or greater than 8 and equal to or less than 40. In that case, the heat resistance of the silicone thermal interface material may be reduced particularly effectively. This is probably because if the number of faces of particles is equal to or greater than 14 and equal to or less than 25, the frequency of occurrence of contact between the particles and the area of contact between them may be increased with an adequate balance struck, thus particularly significantly facilitating the heat transfer between the particles. The maximum peak is preferably located at a point where the number of faces of the particles is equal to or greater than 14 and equal to or less than 25 and more preferably located at a point where the number of faces of the particles is equal to or greater than 14 and equal to or less than 18. In addition, the closer to the point where the number of faces of the particles is 16 the maximum peak is, the better.

The polyhedral alumina filler (B) preferably has a mean particle size equal to or greater than 1 μm and equal to or less than 100 μm, for example. Note that the mean particle size of the polyhedral alumina filler (B) is a median diameter to be calculated based on a particle size distribution obtained by dynamic light scattering.

The polyhedral alumina filler (B) may be treated with a silane coupling agent. Treating the polyhedral alumina filler (B) with a silane coupling agent increases the chances of the polyhedral alumina filler (B) being dispersed sufficiently uniformly in the thermally conductive silicone composition and the silicone thermal interface material, thus making it easier to reduce the heat resistance of the silicone thermal interface material.

The thermally conductive silicone composition may contain a silane coupling agent. This also increases the chances of the polyhedral alumina filler (B) being dispersed sufficiently uniformly in the thermally conductive silicone composition and the silicone thermal interface material, thus making it easier to reduce the heat resistance of the silicone thermal interface material.

The proportion of the polyhedral alumina filler (B) to the entire thermally conductive silicone composition is preferably equal to or greater than 60% by volume. Making this proportion equal to or greater than 60% by volume makes it particularly easy to reduce the heat resistance of the silicone thermal interface material. The proportion of the polyhedral alumina filler (B) is more preferably equal to or greater than 80% by volume. This makes it even easier to reduce the heat resistance of the silicone thermal interface material. The proportion of the polyhedral alumina filler (B) is preferably equal to or less than 90% by volume. This increases the chances of the thermally conductive silicone composition having sufficient flowability and also increases the chances of the silicone thermal interface material having sufficient flexibility.

The thermally conductive silicone composition is preferably liquid at 25° C. The thermally conductive silicone composition preferably has a viscosity equal to or less than 3000 Pa·s at 25° C. This allows the thermally conductive silicone composition to have good moldability. For example, this makes it easier to form the thermally conductive silicone composition into a film shape using a dispenser, for example. In addition, this also makes it easier to defoam the thermally conductive silicone composition, thus reducing the chances of voids being produced in the silicone thermal interface material. Note that the viscosity is a value measured by using an E-type rotational viscometer under the condition including 0.3 rpm.

Optionally, the thermally conductive silicone composition may further contain an additional filler other than the polyhedral alumina filler (B). For example, the thermally conductive silicone composition may contain at least one type selected from the group consisting of any appropriate metal oxide particles, metal nitride particles, metal carbide particles, metal boride particles, and elementary metal particles other than the polyhedral alumina filler (B).

The thermally conductive silicone composition may be prepared by, for example, kneading the above-described components together. If the silicone component (A) is a two-part component, then a thermally conductive silicone composition, consisting of a first part, including a reactive organic silicon compound, of the silicone component (A) and a second part, including a curing agent, of the silicone component (A), may be prepared. The first part and the second part may be mixed together when the thermally conductive silicone composition is used. In that case, the polyhedral alumina filler (B) may be contained in at least one of the first part or the second part.

When a silicone thermal interface material is formed out of the thermally conductive silicone composition, the thermally conductive silicone composition is molded into a film shape by an appropriate method such as press molding, extrusion, or calendar molding. It is also preferable that the thermally conductive silicone composition be molded into a film shape using a dispenser. Subsequently, the film of the thermally conductive silicone composition is heated under a condition according to its chemical makeup and thereby cured. In this manner, a film of the silicone thermal interface material is obtained.

Note that the thermally conductive silicone composition and the silicone thermal interface material do not have to be molded into a film shape but may also be molded into any other appropriate shape. Also, if the silicone component (A) is curable at an ordinary temperature, then the silicone thermal interface material may also be obtained by curing the thermally conductive silicone composition without heating the thermally conductive silicone composition. The silicone thermal interface material includes: a silicone resin matrix made of the silicone component (A); and the polyhedral alumina filler (B) dispersed in the silicone resin matrix.

The silicone thermal interface material contains the polyhedral alumina filler (B), and therefore, tends to have low heat resistance. This is probably because the contact of the filler particles in the silicone thermal interface material would form a path along which the heat may be transferred and the efficiency of heat transfer between the particles would be easily increased by frequent plane contact between the particles in such a situation. Furthermore, the polyhedral alumina filler (B) has a gelatinization ratio equal to or higher than 80%, and therefore, tends to have high thermal conductivity, thus increasing the chances of further increasing the heat transfer efficiency via the particles of the polyhedral alumina filler (B).

If any pressing pressure is applied to the silicone thermal interface material, then the heat resistance tends to decrease particularly significantly in the direction in which the pressing pressure is applied to the silicone thermal interface material. This is probably because, in such a situation, particles of the polyhedral alumina filler (B) are more likely to come into contact with each other in the direction in which the pressing pressure is applied. In this embodiment, the particles often make plane contact with each other as described above. This particularly significantly increases the chances of the heat resistance being reduced by the application of the pressing pressure. Thus, the heat resistance may be reduced even if the pressing pressure is low.

The heat resistance of the silicone thermal interface material is reduced as described above. Thus, in a state where a pressing pressure of 1 MPa is directly applied to the silicone thermal interface material, the heat resistance of the silicone thermal interface material in the direction in which the pressing pressure is applied is preferably equal to or less than 0.8 K/W. This allows the silicone thermal interface material to express excellent thermal conductivity and transfer heat efficiently and smoothly even if the pressing pressure is low. The heat resistance is more preferably equal to or less than 0.7 K/W and is even more preferably equal to or less than 0.6 K/W.

The silicone thermal interface material preferably has an Asker C hardness equal to or less than 40. The Asker C hardness may be measured with, for example, an Asker rubber hardness meter (durometer) type C manufactured by Kobunshi Keiki Co., Ltd. If the Asker C hardness is equal to or less than 40, the silicone thermal interface material may have sufficient flexibility. This makes it easier to adhere the silicone thermal interface material closely to a surface having any of various shapes such as a warped surface or a wavy surface. The Asker C hardness is more preferably equal to or less than 20. Meanwhile, the Asker C hardness may be, for example, equal to or greater than one. Such a low Asker C hardness is achievable by, for example, selecting an appropriate silicone component (A), selecting an appropriate particle size for the polyhedral alumina filler (B), or selecting an appropriate proportion for the polyhedral alumina filler (B).

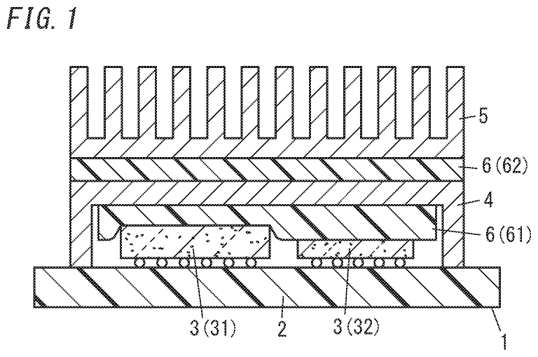

Next, an exemplary electronic device including the silicone thermal interface material will be described. The electronic device 1 shown in FIG. 1 includes a board 2, a chip component 3, a heat spreader 4, a heatsink 5, and two types of thermal interface materials 6 (hereinafter referred to as “TIM1 61” and “TIM2 62,” respectively). In the following description, one of the two types of thermal interface materials 6 will be hereinafter referred to as a “first thermal interface material 61 (TIM1 61)” and the other thermal interface material 6 will be hereinafter referred to as a “second thermal interface material 62 (TIM2 62).” The chip component 3 is mounted on the board 2. The board 2 may be, for example, a printed wiring board. The chip component 3 may be, but do not have to be, a transistor, a CPU, an MPU, a driver IC, or a memory. A plurality of chip components 3 may be mounted on the board 2. In that case, the chip components 3 may have mutually different thicknesses. The heat spreader 4 is mounted on the board 2 to cover the chip components 3. A gap is left between the chip components 3 and the heat spreader 4. The TIM1 61 is disposed in the gap. The heatsink 5 is disposed over the heat spreader 4 and the TIM2 62 is interposed between the heat spreader 4 and the heatsink 5.

The silicone thermal interface material according to this embodiment is applicable to any of the TIM1 61 or the TIM2 62. It is particularly preferable that the TIM1 61 be the silicone thermal interface material according to this embodiment. In that case, pressing pressure may be applied by the heat spreader 4 to the silicone thermal interface material. This increases the chances of bringing the particles of the polyhedral filler in the silicone thermal interface material into contact with each other, thus making it easier for the silicone thermal interface material to have particularly low heat resistance.

Also, if the electronic device 1 includes a plurality of chip components 3 having mutually different thicknesses, then the gap left between the less thick chip component 3 (32) and the heat spreader 4 is wider than the gap left between the thicker chip component 3 (31) and the heat spreader 4. Thus, the pressing pressure applied to the TIM1 61 between the less thick chip component 32 and the heat spreader 4 tends to be lower than the pressing pressure applied to the TIM1 61 between the thicker chip component 31 and the heat spreader 4. Consequently, the pressing pressure applied to the TIM1 61 tends to vary locally. According to this embodiment, however, the silicone thermal interface material contains the polyhedral filler, and therefore, application of the pressing pressure makes it particularly easy to reduce the heat resistance. This increases, even if the pressing pressure applied to the silicone thermal interface material is locally different, the chances of the silicone thermal interface material having low heat resistance as a whole. That is why if the TIM1 61 is the silicone thermal interface material according to this embodiment, then the silicone thermal interface material may transfer the heat generated by the chip components 3 to the heat spreader 4 efficiently, thus making it easier to provide an electronic device 1 with good heat dissipation capability.

### EXAMPLES

Next, more specific examples of this embodiment will be described. Note that the specific examples to be described below are only examples of this embodiment and should not be construed as limiting.

### 1. Preparation of Composition

Compositions were each prepared by mixing a silicone component and a filler. The type of the silicone component and the chemical makeups of the fillers are as shown in the following Table 1. The silicone component and the fillers that were used are specifically as follows:
TES 8553: product number TES 8553, silicone resin manufactured by Dow Corning Toray Co., Ltd.;
Filler 1: a polyhedral alumina filler having a mean particle size of 50 μm, a gelatinization ratio of 83%, 25 faces at a maximum peak of a distribution curve showing a relationship between the number of particles and the number of faces of the particles, and a thermal conductivity of 35 W/m·K;
Filler 2: a polyhedral alumina filler having a mean particle size of 50 μm, a gelatinization ratio of 91%, 18 faces at a maximum peak of a distribution curve showing a relationship between the number of particles and the number of faces of the particles, and a thermal conductivity of 40 W/m·K;
Filler 3: a polyhedral alumina filler having a mean particle size of 50 μm, a gelatinization ratio of 99%, 14 faces at a maximum peak of a distribution curve showing a relationship between the number of particles and the number of faces of the particles, and a thermal conductivity of 45 W/m·K;
Filler 4: a polyhedral alumina filler having a mean particle size of 50 μm, a gelatinization ratio of 75%, 50 faces at a maximum peak of a distribution curve showing a relationship between the number of particles and the number of faces of the particles, and a thermal conductivity of 30 W/m·K;
Filler 5: a polyhedral alumina filler having a mean particle size of 50 μm, a gelatinization ratio of 66%, 80 faces at a maximum peak of a distribution curve showing a relationship between the number of particles and the number of faces of the particles, and a thermal conductivity of 25 W/m·K; and
Filler 6: a polyhedral alumina filler, which had a mean particle size of 50 μm, a gelatinization ratio of 58%, and a thermal conductivity of 20 W/m·K and of which the faces were too many to count.

### 2. Evaluation

(1) Thermal conductivity and heat resistance

Each composition was hot-pressed at a heating temperature of 120° C. and a pressing pressure of 1 MPa for 30 minutes, thereby forming a sample in the shape of sheet having a thickness of 100 μm. This sample was sandwiched between two copper plates and a pressing pressure of 1 MPa was directly applied from the plates to the sample. In this state, the thermal conductivity and heat resistance of the sample were measured at room temperature in the direction in which the pressing pressure was applied by using Dyn TIM Tester manufactured by Mentor Graphics.

(2) Asker C hardness

The Asker C hardness of the sample was measured by using, as a measuring instrument, an Asker rubber hardness meter (durometer) type C manufactured by Kobunshi Keiki Co., Ltd.

(3) Viscosity

The viscosity of the composition was measured under the condition including 0.3 rpm by using, as a measuring instrument, E type viscometer (model number: RC-215) manufactured by Toki Sangyo Co., Ltd.

TABLE 1

| | | Examples | | | | | | Comparative examples | | |
|---|---|---|---|---|---|---|---|---|---|---|
| | | 1 | 2 | 3 | 4 | 5 | 6 | 1 | 2 | 3 |
| Silicone component | | TES | TES | TES | TES | TES | TES | TES | TES | TES |
| | | 8553 | 8553 | 8553 | 8553 | 8553 | 8553 | 8553 | 8553 | 8553 |
| Filler | Filler 1 (gelatinization | 70 | | | | | | | | |
| content | ratio 83 and 25 faces at | | | | | | | | | |
| (vol %) | peak) | | | | | | | | | |
| | Filler 2 (gelatinization | | 70 | | | | | | | |
| | ratio 91 and 18 faces at | | | | | | | | | |
| | peak) | | | | | | | | | |
| | Filler 3 (gelatinization | | | 70 | 75 | 80 | 85 | | | |
| | ratio 99 and 14 faces at | | | | | | | | | |
| | peak) | | | | | | | | | |
| | Filler 4 (gelatinization | | | | | | | 70 | | |
| | ratio 75 and 50 faces at | | | | | | | | | |
| | peak) | | | | | | | | | |
| | Filler 5 (gelatinization | | | | | | | | 70 | |
| | ratio 66 and 80 faces at | | | | | | | | | |
| | peak) | | | | | | | | | |
| | Filler 6 (gelatinization | | | | | | | | | 70 |
| | ratio 58 and | | | | | | | | | |
| | uncountable faces at | | | | | | | | | |
| | peak) | | | | | | | | | |

| | | | | | | | | | |
|---|---|---|---|---|---|---|---|---|---|
| Thermal conductivity (W/m · K) | 8.0 | 8.5 | 9.0 | 9.5 | 10.0 | 10.5 | 5.5 | 5.0 | 4.5 |
| Heat resistance (K/W) | 0.8 | 0.7 | 0.5 | 0.45 | 0.4 | 0.4 | 0.9 | 1.2 | 1.3 |
| Asker C hardness | 11 | 12 | 13 | 15 | 17 | 20 | 10 | 9 | 8 |
| Viscosity (Pa · s) | 2000 | 2100 | 2200 | 2300 | 2500 | 2800 | 1900 | 1800 | 1700 |

1. A thermally conductive silicone composition containing:
a silicone component (A); and
a polyhedral alumina filler (B) having a gelatinization ratio equal to or higher than 80%.

2. The thermally conductive silicone composition of claim 1, wherein
the polyhedral alumina filler (B) has a thermal conductivity equal to or greater than 30 W/m·k.

3. The thermally conductive silicone composition of claim 1, wherein
a distribution curve showing a relationship between a numerical number of particles and a numerical number of faces of particles of the polyhedral alumina filler (B) has a maximum peak at a point where the numerical number of faces of the particles is equal to or greater than 8 and equal to or less than 40.

4. A silicone thermal interface material made of the thermally conductive silicone composition of claim 1,
the silicone thermal interface material comprising:
a silicone resin matrix made of the silicone component (A); and
the polyhedral alumina filler (B) dispersed in the silicone resin matrix.

5. The silicone thermal interface material of claim 4, wherein
the silicone thermal interface material has an Asker C hardness equal to or less than 20.

6. The thermally conductive silicone composition of claim 2, wherein
a distribution curve showing a relationship between a numerical number of particles and a numerical number of faces of particles of the polyhedral alumina filler (B) has a maximum peak at a point where the numerical number of faces of the particles is equal to or greater than 8 and equal to or less than 40.

7. A silicone thermal interface material made of the thermally conductive silicone composition of claim 2,
the silicone thermal interface material comprising:
a silicone resin matrix made of the silicone component (A); and
the polyhedral alumina filler (B) dispersed in the silicone resin matrix.

8. A silicone thermal interface material made of the thermally conductive silicone composition of claim 3,
the silicone thermal interface material comprising:
a silicone resin matrix made of the silicone component (A); and
the polyhedral alumina filler (B) dispersed in the silicone resin matrix.

9. A silicone thermal interface material made of the thermally conductive silicone composition of claim 6,
the silicone thermal interface material comprising:
a silicone resin matrix made of the silicone component (A); and
the polyhedral alumina filler (B) dispersed in the silicone resin matrix.

10. The silicone thermal interface material of claim 7, wherein
the silicone thermal interface material has an Asker C hardness equal to or less than 20.

11. The silicone thermal interface material of claim 8, wherein
the silicone thermal interface material has an Asker C hardness equal to or less than 20.

12. The silicone thermal interface material of claim 9, wherein
the silicone thermal interface material has an Asker C hardness equal to or less than 20.
